(19) United States
(12) Patent Application Publication
(10) Pub. No.: US 2023/0095066 A1
(43) Pub. Date: Mar. 30, 2023

(54) DISPLAY DEVICE

(71) Applicant: Samsung Display Co., LTD., Yongin-si (KR)

(72) Inventors: WOONGSIK KIM, Hwaseong-si (KR); JUNGI KIM, Hwaseong-si (KR); DONGHWAN BAE, Seoul (KR); JIN-SU BYUN, Seoul (KR); JUNGMIN CHOI, Hwaseong-si (KR)

(21) Appl. No.: 17/842,993

(22) Filed: Jun. 17, 2022

(30) Foreign Application Priority Data
Sep. 27, 2021 (KR) 10-2021-0127066

(51) Int. Cl. H01L 27/32; H01L 51/52; G06F 3/041

(52) U.S. Cl. CPC H01L 27/3216; H01L 51/5284; H01L 51/5275; G06F 3/0412; H01L 27/3246; H01L 27/323

(57) ABSTRACT

A display device includes a first light emitting layer having a first length in a first direction and emitting a first light, a second light emitting layer having a second length in the first direction and emitting a second light different from the first light, a first refractive layer on the first light emitting layer and the second light emitting layer and including a plurality of refractive patterns having a first refractive index, a second refractive layer which covers the first refractive layer and has a second refractive index lower than the first refractive index, and a plurality of first black matrices on the second refractive layer and adjacent to the first light emitting layer and the second light emitting layer in a second direction crossing the first direction.

This application claims priority to Korean Patent Application No. 10-2021-0127066, filed on Sep. 27, 2021, and all the benefits accruing therefrom under 35 U.S.C. § 119, the content of which in its entirety is herein incorporated by reference.

### BACKGROUND

### 1. Field

Embodiments relate to a display device. More particularly, embodiments relate to a display device capable of displaying an image.

### 2. Description of the Related Art

A display device may include a plurality of pixels. Each of the plurality of pixels may include a plurality of sub pixels. The plurality of sub pixels may emit light of different colors. For example, the plurality of sub pixels may include a red sub pixel, a blue sub pixel, and a green sub pixel. Each of the plurality of sub pixels may include a plurality of driving elements and a light emitting layer. Also, the display device may further include components in the plurality of pixels. Examples of the components include refractive layers having different refractive indices, a light blocking layer that blocks light emitted, an encapsulation layer, a glass layer, a touch sensing layer, and the like.

Light emitted from the display device may be emitted in various directions, so that an image displayed on the display device may be viewed from various angles. However, when an image of the display device is viewed from various angles, a problem such as a decrease in luminance may occur. Accordingly, various studies for adjusting the viewing angle of the display device are being conducted.

### SUMMARY

Embodiments provide a display device with improved viewing angle.

An embodiment of a display device includes a first light emitting layer having a first length in a first direction and emitting a first light, a second light emitting layer having a second length in the first direction and emitting a second light different from the first light, a plurality of refractive patterns having a first refractive index, a first refractive layer on the refractive patterns and including a second refractive index lower than the first refractive index, and a plurality of first black matrices on the first refractive layer and adjacent to the first light emitting layer and the second light emitting layer in a second direction crossing the first direction in a plan view.

In an embodiment, the first length may be equal to the second length.

In an embodiment, the first light emitting layer may have a first width in the second direction, the second light emitting layer may have a second width in the second direction, the first length may be larger than the first width, and the second length may be larger than the second width.

In an embodiment, the refractive patterns, in a plan view, may include a first refractive pattern which overlaps the first light emitting layer and a second refractive pattern which overlaps the second light emitting layer.

In an embodiment, the first refractive pattern may have a third length greater than the first length in the first direction and a third width greater than the first width in the second direction, and the second refractive pattern may have a fourth length greater than the second length in the first direction and a fourth width greater than the second width in the second direction.

In an embodiment, the first length may be larger than the second length.

In an embodiment, the first light emitting layer may have a first width in the second direction, the second light emitting layer may have a second width in the second direction, the first length may be larger than the first width, and the second length may be the larger than the second width.

In an embodiment, the first width and the second width may be the same.

In an embodiment, the refractive patterns, in a plan view, may include a first refractive pattern which overlaps the first light emitting layer and a second refractive pattern which overlaps the second light emitting layer.

In an embodiment, the first refractive pattern may have a third length greater than the first length in the first direction and a third width greater than the first width in the second direction, and the second refractive pattern may have a fourth length greater than the second length in the first direction and a fourth width greater than the second width in the second direction.

In an embodiment, the plurality of first black matrices may include a first light blocking pattern adjacent to the first light emitting layer and a second light blocking pattern adjacent to the second light emitting layer.

In an embodiment, the first light blocking pattern may have the first length in the first direction, and the second light blocking pattern may have the first length in the first direction.

In an embodiment, the first light blocking pattern may have the first length in the first direction, and the second light blocking pattern may have the second length in the second direction.

In an embodiment, heights of the refractive patterns in a third direction crossing each of the first direction and the second direction may be about 3.2 micrometers to about 5 micrometers.

In an embodiment, the display device may further include a second refractive layer which covers the first black matrices and a plurality of second black matrices on the second refractive layer and overlapping the plurality of first black matrices in a plan view.

In an embodiment, the display device may further include an encapsulation layer between the first light emitting layer and the second light emitting layer, and the first refractive layer, and a touch sensing layer between the encapsulation layer and the first refractive layer.

In an embodiment, the display device may further include a touch sensing layer between the encapsulation layer and the first refractive layer.

An embodiment of a display device includes a first light emitting layer having a first length in a first direction and emitting a first light, a second light emitting layer having the first length in the first direction and emitting the first light, a third light emitting layer having a second length in the first direction and emitting a second light different from the first light, and a fourth light emitting layer having the second length in the first direction and emitting the second light, a plurality of refractive patterns having a first refractive index, a first refractive layer on the refractive patterns and having a second refractive index lower than the first refractive index, and a plurality of first black matrices on the second refractive layer and adjacent to each of the first to fourth light emitting layers in a second direction crossing the first direction in a plan view.

In an embodiment, the first length may be larger than the second length, and the first light emitting layer may have a first width in the second direction, the second light emitting layer may have a second width in the second direction, the third light emitting layer may have a third width in the second direction, and the fourth light emitting layer may have a fourth width in the second direction.

In an embodiment, the first width may be larger than the second width, and the third width is larger than the fourth width.

In an embodiment, the first length and the second length may be the same.

In an embodiment, in a plan view, the refractive patterns may include a first refractive pattern overlapping the first light emitting layer and having a third length larger than the first length in the first direction, a second refractive pattern overlapping the second light emitting layer and having the third length in the first direction, a third refractive pattern overlapping the third light emitting layer and having a fourth length larger than the second length in the first direction and a fourth refractive pattern overlapping the fourth light emitting layer and having the fourth length in the first direction.

In an embodiment, in a plan view, an area of the first refractive pattern is larger than an area of the first light emitting layer, an area of the second refractive pattern is larger than an area of the second light emitting layer, an area of the third refractive pattern is larger than an area of the third light emitting layer, an area of the fourth refractive pattern is larger than an area of the fourth light emitting layer.

In an embodiment, heights of the refractive patterns in a third direction crossing each of the first direction and the second direction may be about 3.2 micrometers to about 5 micrometers.

In an embodiment, the display device may further include a second refractive layer which covers the plurality of first black matrices, and second black matrices on the second refractive layer and overlapping the plurality of first black matrices, in a plan view.

In an embodiment, the display device may further include an encapsulation layer between the first to fourth light emitting layers, and the first refractive layer, and a touch sensing layer between the encapsulation layer and the first refractive layer.

In an embodiment, the display device may further include a glass layer between the first to fourth light emitting layers, and the first refractive layer.

One or more embodiment of a display device includes a first light emitting layer having a first length in a first direction and emitting a first light, a second light emitting layer having a second length in the first direction and emitting a second light different from the first light, a plurality of refractive patterns having a first refractive index, a first refractive layer on the refractive patterns and having a second refractive index lower than the first refractive index, and a plurality of first black matrices, on the first refractive layer and adjacent to the first light emitting layer and the second light emitting layer in a second direction crossing the first direction in a plan view.

The first light emitting layer and the second light emitting layer may have different sizes, the first length may be larger than the first width, and the second length may be larger than the second width. Accordingly, the viewing angle (or emission angle) of the light emitted in the second direction may be narrowly adjusted, and the viewing angle of the light emitted in the second direction may be narrowed due to the plurality of refractive patterns and the first refractive layer. In addition, the plurality of first black matrices may block light emitted in the second direction. Accordingly, the viewing angle of the light emitted in the second direction may be narrowly adjusted. In addition, when the plurality of refractive patterns have a height of about 3.2 micrometers to about 5 micrometers, light may be refracted more than in the related art, and thus light emitted from the lower portion of the display device may be effectively refracted. Through this, the luminance characteristic of the light emitted from the display device may also be improved.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a plan view schematically illustrating an embodiment of a pixel included in the display device of FIG. 1.

FIG. 3 is a plan view schematically illustrating an embodiment of a pixel included in the display device of FIG. 1.

FIG. 4 is a plan view schematically illustrating an embodiment of a pixel included in the display device of FIG. 1.

FIG. 5 is a plan view schematically illustrating an embodiment of a pixel included in the display device of FIG. 1.

FIG. 6 is a plan view schematically illustrating an embodiment of a pixel included in the display device of FIG. 1.

FIG. 7 is a plan view schematically illustrating an embodiment of a pixel included in the display device of FIG. 1.

FIG. 8 is a plan view schematically illustrating an embodiment of a pixel included in the display device of FIG. 1.

FIG. 9 is a plan view schematically illustrating an embodiment of a pixel included in the display device of FIG. 1.

FIG. 10 is a cross-sectional view schematically illustrating an embodiment of a cross-section taken along line I-I′ of FIG. 2.

FIG. 11 is a cross-sectional view schematically illustrating an embodiment of a cross-section taken along line I-I′ of FIG. 2.

FIG. 12 is a cross-sectional view schematically illustrating an embodiment of a cross-section taken along line I-I′ of FIG. 2.

FIG. 13 is a cross-sectional view schematically illustrating an embodiment of a cross-section taken along line I-I′ of FIG. 2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

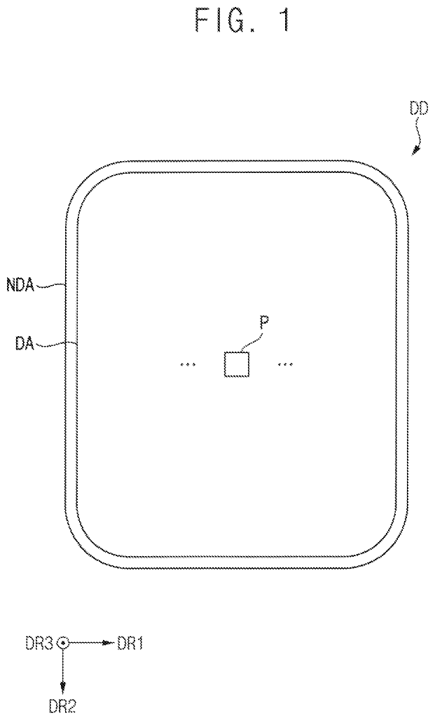

FIG. 1 is a plan view illustrating a display device DD according to an embodiment.

Referring to FIG. 1, the display device DD may include a display area DA and a non-display area NDA. The non-display area NDA may be disposed adjacent to the display area DA, such as to surround the display area DA. However, in order to reduce a dead space, the non-display area NDA may be disposed only on one side of the display area DA.

The display device DD may include a pixel P provided in plural including a plurality of pixels P. The plurality of pixels P may be disposed in the display area DA. The plurality of pixels P may be arranged in various patterns in the display area DA. In an embodiment, for example, the plurality of pixels P may be generally disposed in the display area DA in a matrix form. That is, the plurality of pixels P may be disposed along a row extending in (or along) the first direction DR1 and a column extending in (or along) the second direction DR2. The first direction DR1 and the second direction DR2 may cross each other. A plane may be defined by the first direction DR1 and the second direction DR2 crossing each other. The display device DD may emit light through (or at) the plurality of pixels P. Light may be emitted along a thickness direction of the display device, such as in a third direction DR3 crossing each of the first and second directions DR1 and DR2.

The plurality of pixels P may include a light emitting layer. The light emitting layer may be an organic light emitting layer or an inorganic light emitting layer. Also, the plurality of pixels P may include a plurality of driving elements for driving the light emitting layer. The light emitting layer may be connected to the plurality of driving elements. The plurality of driving elements may include a transistor and a capacitor.

Driving circuits may be disposed in the non-display area NDA. The driving circuits may include a data driving circuit, a gate driving circuit, and a light emitting driving circuit. Also, a circuit board may be disposed in the non-display area NDA to receive a signal (e.g., an electrical signal) transmitted from outside the circuit board or outside the display device DD. The driving circuits may receive the signal and transmit the signal to the plurality of pixels P. The plurality of pixels P may emit light based on the signal.

When a reflective member capable of reflecting light, such as glass or a mirror, is disposed around the display device DD, light emitted from the display device DD may be reflected by the reflective member. Accordingly, it may be difficult to recognize light emitted from the display device DD due to the reflected light. Accordingly, in order to improve recognition of the light emitted from the display device DD, light emitted from the display device DD which is incident on the reflective member may be reduced or effectively prevented. In an embodiment, for example, the reflective member may be disposed along the second direction DR2 of the display device DD. In this case, when the light that is emitted from the display device DD toward the second direction DR2 is blocked, the light may not be reflected by the reflective member. That is, recognition of the light emitted from the display device DD may be improved by narrowing the viewing angle of the display device DD. In this case, a luminance of the display device DD may be improved as the viewing angle is reduced.

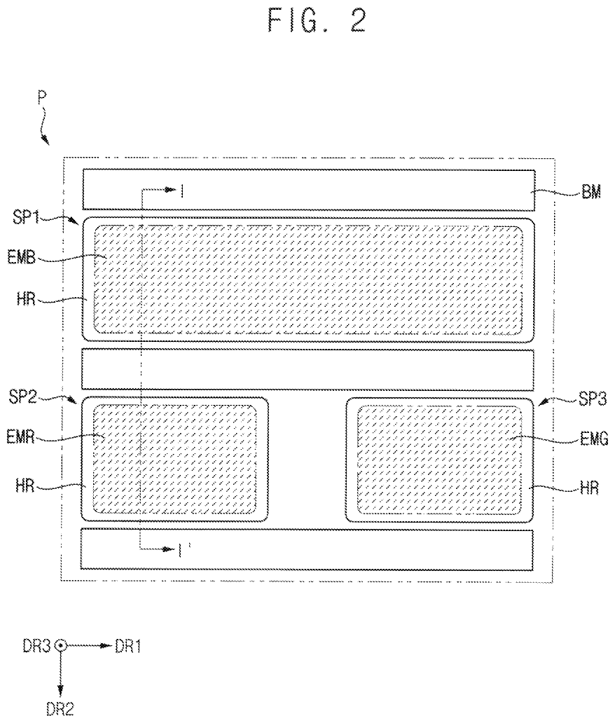

FIG. 2 is a plan view schematically illustrating an embodiment of a pixel P included in the display device DD of FIG. 1.

Referring to FIG. 2, the pixel P may include first to third sub pixels SP1, SP2, SP3. The first to third sub pixels SP1, SP2, SP3 may have different shapes in a plan view (e.g., a planar shape along the plane defined by the first and second directions DR1 and DR2 which cross each other). In embodiments, the first sub pixel SP1 may have a larger length in the first direction DR1 than lengths of the second sub pixel SP2 and the third sub pixel SP3. The lengths may define a major dimension (or maximum dimension) of the planar shape, and major dimensions of the first to third sub pixels SP1, SP2, SP3 may be extended along the first direction DR1, without being limited thereto.

In the first sub pixel SP1, a first light emitting layer EMB may emit first light. The first light emitting layer EMB may emit blue light. In the second sub pixel SP2, the second light emitting layer EMR may emit light. The second light emitting layer EMR may emit red light. In the third sub pixel SP3, the third light emitting layer EMG may emit light. The third light emitting layer EMG may emit green light. However, this is only an example, and the light emitted by the first sub pixel SP1 having a long length (e.g., the major dimension) in the first direction DR1 may be green or red.

Each sub pixel may have dimensions (e.g., length, width, etc.) extended along the plane, to define the planar shape. The first to third sub pixels SP1, SP2, SP3 may have a length and a width, respectively. The first sub pixel SP1 may have a first length in the first direction DR1 and may have a first width in the second direction DR2. The second sub pixel SP2 may have a second length in the first direction DR1 and may have a second width in the second direction DR2. The third sub pixel SP3 may have a third length in the first direction DR1 and may have a third width in the second direction DR2. The first length may be greater than the second length and the third length. The first to third widths may be the same as or different from each other.

Although not illustrated in a plan view, a refractive pattern HR provided in plural including a plurality of refractive patterns HR may be disposed on the first to third light emitting layers EMB, EMR, EMG. Each of the refractive patterns HR may have a larger area (e.g., larger planar area) than planar areas of the first to third light emitting layers EMB, EMR, EMG.

Each of the first to third light emitting layers EMB, EMR, EMG (e.g., plurality of light emitting layer within a light emitting element layer) may have a length in the first direction DR1 greater than a width in the second direction DR2, to define a major dimension of a light emitting layer along the first direction DR1. Accordingly, the first to third light emitting layers EMB, EMR, EMG may adjust light emission so that light emitted in the second direction DR2 may be emitted in the third direction DR3 while securing a light emitting area. In this case, the first to third light emitting layers EMB, EMR, EMG may emit light while having a wide viewing angle in the first direction DR1.

Although not illustrated in a plan view, a black matrix BM provided in plural including a plurality of black matrices BM may be disposed on the refractive patterns HR. The plurality of black matrices BM may be disposed adjacent to the first to third light emitting layers EMB, EMR, EMG in the second direction DR2, in a plan view. The plurality of black matrices BM may block light emitted in the second direction DR2. Accordingly, a viewing angle of the display device DD (or a light emission angle) in the second direction DR2 may be narrowed.

The black matrices BM include a first light blocking pattern, a second light blocking pattern and a third light blocking pattern arranged in order in the second direction DR2. Within the plurality of light blocking patterns, a light blocking pattern may be continuous along the first direction DR1 or may be disconnected along the first direction DR1 to define a plurality of sub-light blocking patterns. Referring to FIG. 2, one of the light blocking patterns among the plurality of black matrices BM having a long length along the first direction DR1, may correspond to a plurality of sub pixels arranged along the first direction DR1.

In the display device DD according to an embodiment, by disposing the first to third sub pixels SP1, SP2, SP3 having a long length in the first direction DR1, respectively, and by disposing the plurality of black matrices BM in the second direction DR2 of the plurality of first to third sub pixels SP1, SP2, SP3, the display device DD may adjust the viewing angle (or light emission angle) of light emitted in the second direction DR2. Referring to FIG. 2, along the second direction DR2, the black matrices BM may alternate with different color sub pixels.

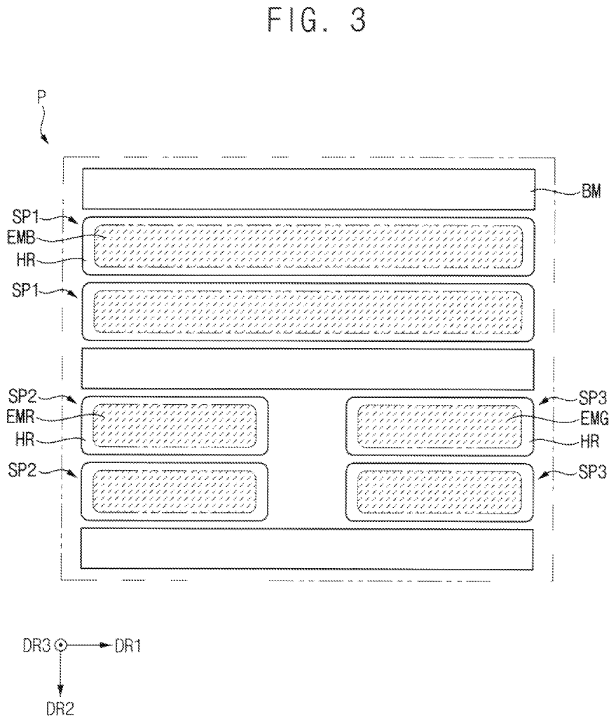

FIG. 3 is a plan view schematically illustrating an embodiment of a pixel P included in the display device DD of FIG. 1.

Referring to FIG. 3, in embodiments, two sub pixels may be disposed between the black matrices BM. Along the second direction DR2, more than one sub pixel arranged directly adjacent to each other may define a sub pixel group or a light emitting layer group. A sub pixel group (or a light emitting layer group) may emit a same (color) light as each other, without being limited thereto. In an embodiment, for example, two first sub pixels SP1 each including the first light emitting layer EMB, may be disposed between the black matrices BM which are consecutive along the second direction DR2 (e.g., adjacent black matrices BM among the black matrices BM). In addition, two second sub pixels SP2 each including the second light emitting layer EMR, are disposed between black matrices BM which are consecutive along the second direction DR2, and two third sub pixels SP3 each including the third light emitting layer EMG are disposed between adjacent black matrices BM which are consecutive along the second direction DR2.

Referring to FIG. 3, along the second direction DR2, the black matrices BM may alternate with the light emitting layer groups. In an embodiment, for example, a light emitting element layer includes a plurality of first light emitting layers EMB each having a first length in the first direction DR1 and each emitting a first light, the plurality of first light emitting layers EMB directly adjacent to each other in the second direction DR2 crossing the first direction DR1 to define a light emitting layer group, and a second light emitting layer EMR and a third light emitting layer EMG each adjacent in the second direction DR2 to the light emitting layer group, each having a second length in the first direction DR1 and each emitting a second light different from the first light. Still referring to FIG. 3, instead of the second light emitting layer EMR and a third light emitting layer EMG, the embodiment may consider two of the second light emitting layer EMR directly adjacent to each other in the second direction DR2 as the second/third light emitting layer and/or two of the third light emitting layer EMG directly adjacent to each other in the second direction DR2 as the second/third light emitting layer.

A sum of areas (e.g., a sum of planar areas) of the two sub pixels SP1 of FIG. 3 may be equal to an area (e.g., the planar area) of the one sub pixel SP1 of FIG. 2. Alternatively, a planar area of each of the two sub pixels SP1 of FIG. 3 may be substantially the same as the area of the one sub pixel SP1 of FIG. 2. The same may be applied to the second sub pixel SP2 and the third sub pixel SP3.

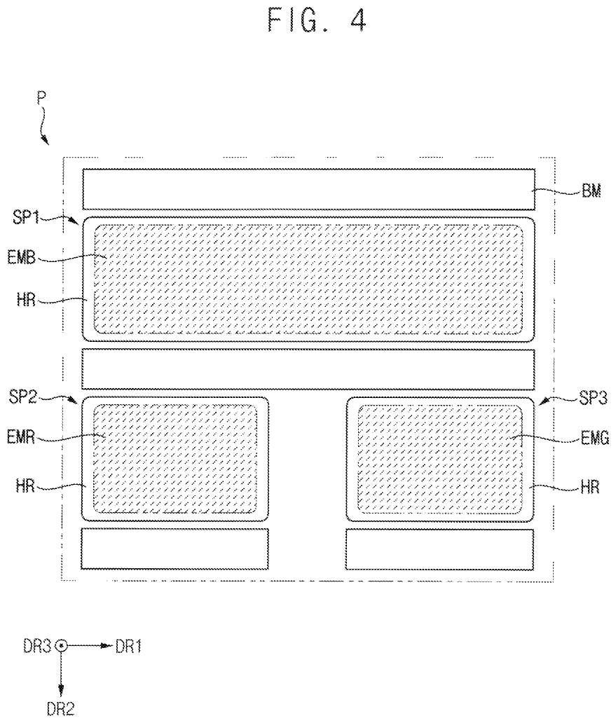

FIG. 4 is a plan view schematically illustrating an embodiment of a pixel P included in the display device DD of FIG. 1.

Referring to FIG. 4, in embodiments, the black matrices BM may have substantially the same length as the length of adjacent sub pixels in the first direction DR1. That is, the black matrices BM may be arranged along the first direction DR1 and have a long length along the first direction DR1, such that the black matrices BM may respectively correspond to a plurality of sub pixels arranged along the first direction DR1. In an embodiment, for example, the black matrices BM adjacent to the first sub pixel SP1 in the second direction DR2 (e.g., closest to the first sub pixel SP1 along the second direction DR2), may have a length substantially equal to the length of the first sub pixel SP1 in the first direction DR1. The black matrices BM adjacent to the second sub pixel SP2 in the second direction DR2 may have substantially the same length as the length of the second sub pixel SP2 in the first direction DR1. The black matrices BM adjacent to the third sub pixel SP3 in the second direction DR2 may have substantially the same length as the length of the third sub pixel SP3 in the first direction DR1. Through this, it is possible to reduce a total planar area of the black matrices BM within the pixel P. Referring to FIG. 4, the black matrices BM may be disconnected from each other along both the first direction DR1 and the second direction DR2.

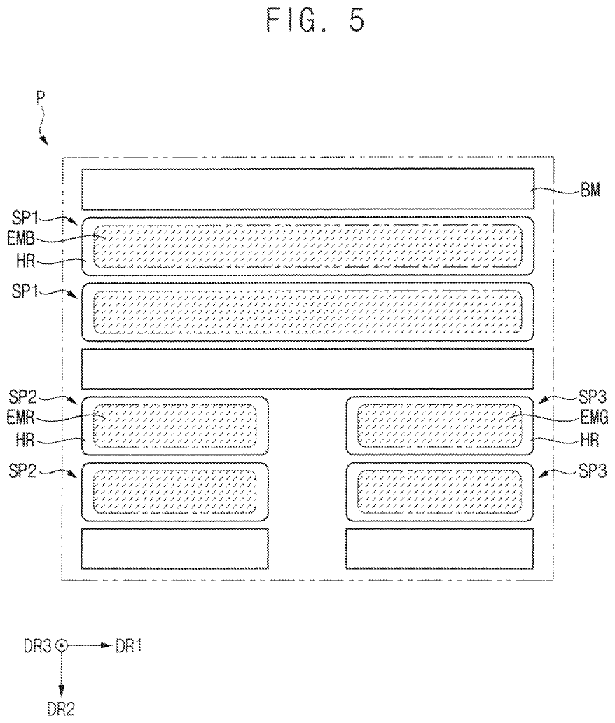

FIG. 5 is a plan view schematically illustrating an embodiment of a pixel P included in the display device DD of FIG. 1.

Referring to FIG. 5, in embodiments, two sub pixels may be disposed between the black matrices BM. In an embodiment, for example, two first sub pixels SP1 each including the first light emitting layer EMB, may be disposed between the black matrices BM. In addition, two second sub pixels SP2 each including the second light emitting layer EMR may be disposed between the black matrices BM, and two third sub pixels SP3 each including the third light emitting layer EMG may be disposed between the black matrices BM.

A sum of an areas of the two sub pixels SP1 of FIG. 5 may be equal to an area of the one sub pixel SP1 of FIG. 4. Alternatively, an area of each of the two sub pixels SP1 of FIG. 5 may be substantially the same as the area of the one sub pixel SP1 of FIG. 4. The same may be applied to the second sub pixel SP2 and the third sub pixel SP3.

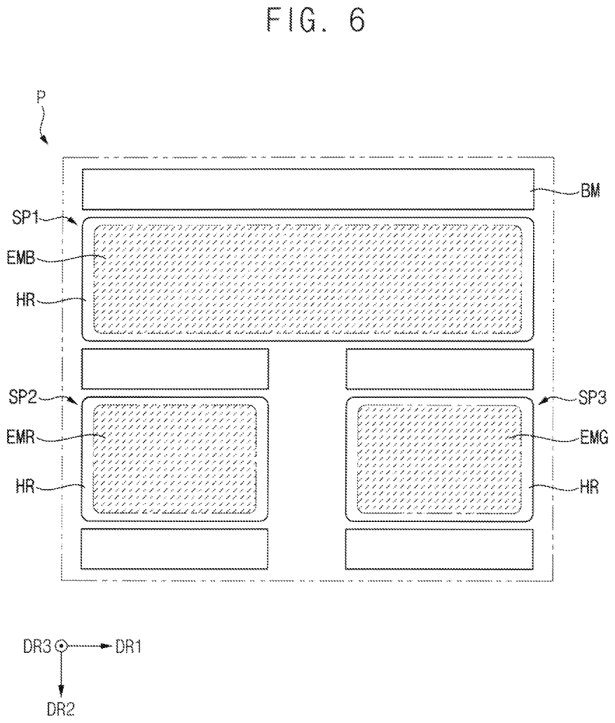

FIG. 6 is a plan view schematically illustrating an embodiment of a pixel P included in the display device DD of FIG. 1.

Referring to FIG. 6, the black matrix BM adjacent to the first sub pixel SP1 in a direction opposite to the second direction DR2, may have a length substantially equal to the length of the first sub pixel SP1 in the first direction DR1. The black matrices BM adjacent to the second sub pixel SP2 along the second direction DR2 may have substantially the same length as the length of the second sub pixel SP2 in the first direction DR1. The black matrices BM adjacent to the third sub pixel SP3 along the second direction DR2 may have substantially the same length as the length of the third sub pixel SP3 in the first direction DR1.

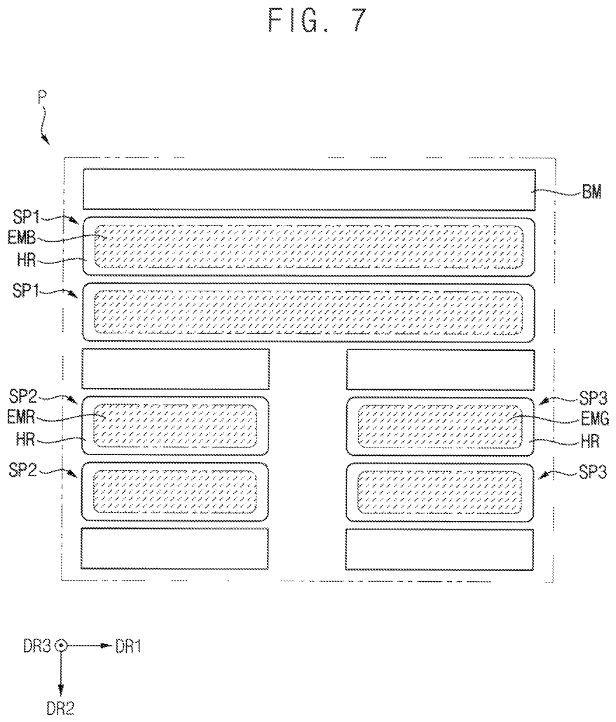

FIG. 7 is a plan view schematically illustrating an embodiment of a pixel P included in the display device DD of FIG. 1.

Referring to FIG. 7, in embodiments, two sub pixels may be disposed between the black matrices BM. In an embodiment, for example, two first sub pixels SP1 each including the first light emitting layer EMB may be disposed between the black matrices BM. In addition, two second sub pixels SP2 each including the second light emitting layer EMR may be disposed between the black matrices BM, and two third sub pixels SP3 each including the third light emitting layer EMG may be disposed between the black matrices BM.

A sum of the areas of the two sub pixels SP1 of FIG. 7 may be equal to an area of one sub pixel SP1 of FIG. 6. Alternatively, an area of each of the two sub pixels SP1 of FIG. 7 may be substantially the same as the area of the one sub pixel SP1 of FIG. 6. The same may be applied to the second sub pixel SP2 and the third sub pixel SP3.

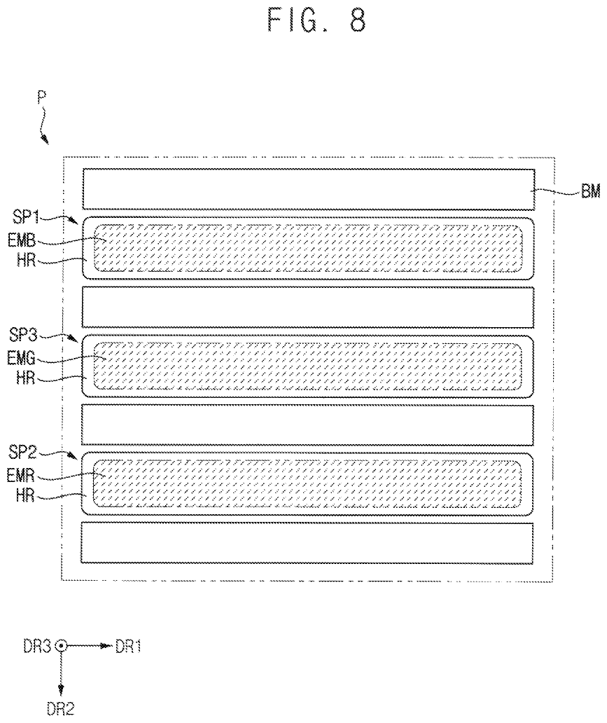

FIG. 8 is a plan view schematically illustrating an embodiment of a pixel P included in the display device DD of FIG. 1.

Referring to FIG. 8, the first to third sub pixels SP1, SP2, SP3 may have substantially the same length in the first direction DR1. A width in the second direction DR2 of the first to third sub pixels SP1, SP2, SP3 may be smaller than a length in the first direction DR1. In this case, the viewing angle of the light emitted in the second direction DR2 may be narrowed. Each of the first to third sub pixels SP1, SP2, SP3 may have the same width in the second direction DR2 or may have different widths in the second direction DR2.

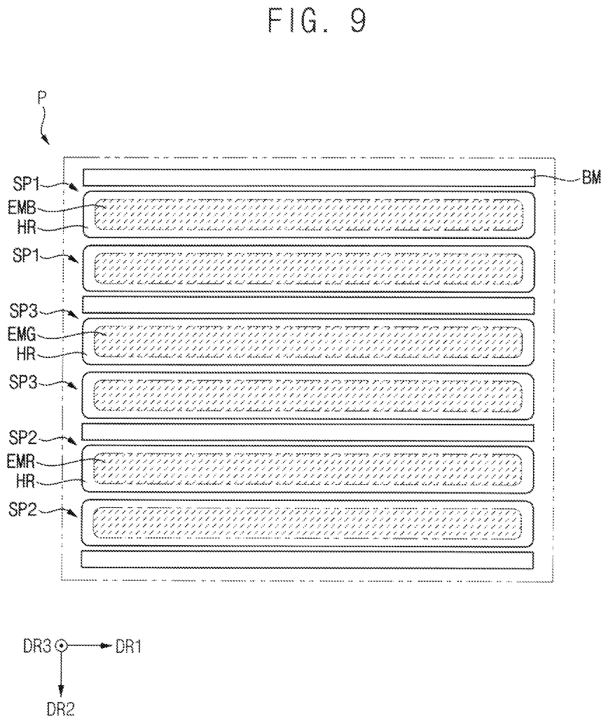

FIG. 9 is a plan view schematically illustrating an embodiment of a pixel P included in the display device DD of FIG. 1.

Referring to FIG. 9, in embodiments, two sub pixels among a plurality of sub pixels may be disposed between the black matrices BM. That is, the black matrices BM may alternate with a plurality of sub pixel groups, along the second direction DR2. In an embodiment, for example, two first sub pixels SP1 each including the first light emitting layer EMB within a first sub pixel group may be disposed between the black matrices BM. In addition, two second sub pixels SP2 each including the second light emitting layer EMR within a second sub pixel group may be disposed between the black matrices BM, and two third sub pixels SP3 each including the third light emitting layer EMG with a third sub pixel group may be disposed between the black matrices BM.

A sum of areas of the two sub pixels SP1 of FIG. 9 may be equal to an area of one sub pixel SP1 of FIG. 8. Alternatively, an area of each of the two sub pixels SP1 of FIG. 9 may be substantially the same as the area of the one sub pixel SP1 of FIG. 8. The same may be applied to the second sub pixel SP2 and the third sub pixel SP3.

The various arrangements of the pixels P described with reference to FIGS. 2 to 9 may be used in combination within the display area DA. In an embodiment, for example, the display device DD may include a plurality of pixels P, and all of the plurality of pixels P may have the same sub pixel structure of one of FIGS. 2 to 9. Alternatively, a first portion of the plurality of pixels P may have the sub pixel arrangement of any one of FIGS. 2 to 9, and a second portion of the plurality of pixels P may have a sub pixel arrangement other than the sub pixel arrangement of the any one of FIGS. 2 to 9.

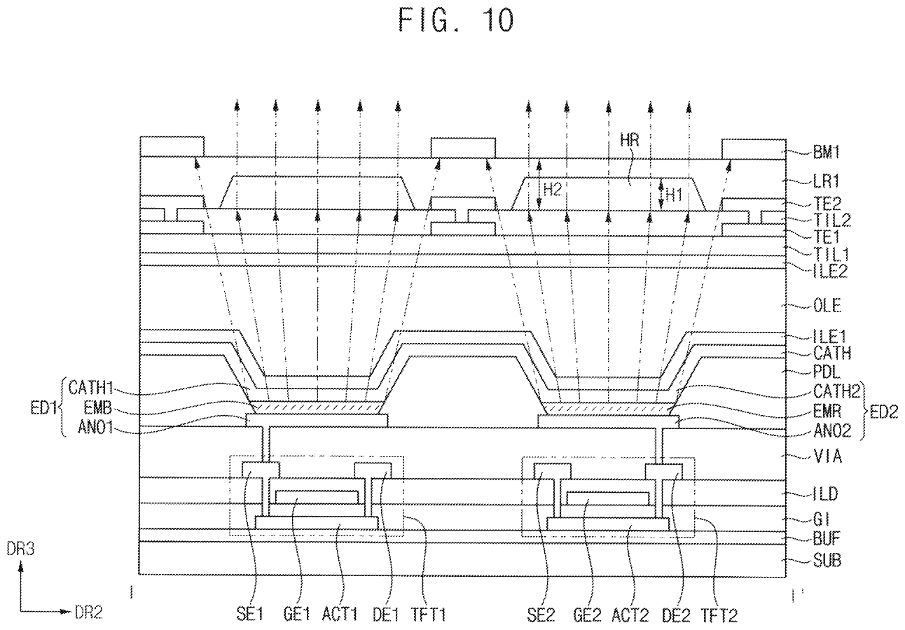

FIG. 10 is a cross-sectional view schematically illustrating an embodiment of a cross-section taken along line I-I′ of FIG. 2.

Referring to FIGS. 1, 2 and 10, the display device DD may include a substrate SUB, a buffer layer BUF, a gate insulating layer GI, an interlayer insulating layer ILD, a via insulating layer VIA, a first transistor TFT1, a second transistor TFT2, a first light emitting diode ED1 (e.g., first light emitting element), a second light emitting diode ED2 (e.g., second light emitting element), a pixel defining layer PDL, a first inorganic thin film encapsulation layer ILE1, an organic thin film encapsulation layer OLE, a second inorganic thin film encapsulation layer ILE2, a first insulating layer TILL first touch electrodes TE1, a second insulating layer TIL2, second touch electrodes TE2, a first refractive layer LR1 including refractive patterns HR arranged therein, and first black matrices BM1.

The first transistor TFT1 may include a first active layer ACT1, a first gate electrode GE1, a first source electrode SE1, and a first drain electrode DE1. The second transistor TFT2 may include a second active layer ACT2, a second gate electrode GE2, a second source electrode SE2, and a second drain electrode DE2.

The first light emitting diode ED1 may include a first anode electrode ANO1 (e.g., first electrode), a first light emitting layer EMB, and a first cathode electrode CATH1 (e.g., second electrode facing the first electrode). The second light emitting diode ED2 may include a second anode electrode ANO2, a second light emitting layer EMR, and a second cathode electrode CATH2. The first cathode electrode CATH1 and the second cathode electrode CATH2 may be integrally formed. That is, each of the first cathode electrode CATH1 and the second cathode electrode CATH2 may be defined as a portion of the cathode electrode CATH as a second electrode common to a plurality of sub pixels.

The substrate SUB may include a flexible material or a rigid material. In an embodiment, for example, the substrate SUB may have flexible characteristics by including a polymer material such as polyimide. Alternatively, for example, the substrate SUB may have rigid characteristics by including a material such as glass.

A buffer layer BUF may be disposed on the substrate SUB. The buffer layer BUF may include an inorganic insulating material. Examples of the material that can be used as the buffer layer BUF may include silicon oxide (“SiOx”), silicon nitride (“SiNx”), silicon oxynitride (“SiON”), and the like. These may be used alone or in combination with each other. The buffer layer BUF may block metal atoms or impurities from diffusing into the first and second active layers ACT1, ACT2. Also, the buffer layer BUF may control the rate of heat provided to the first and second active layers ACT1, ACT2 during a crystallization process for forming the first and second active layers ACT1, ACT2.

The first and second active layers ACT1, ACT2 may be disposed on the buffer layer BUF. In embodiments, the first and second active layers ACT1, ACT2 may include a silicon semiconductor. In an embodiment, for example, the first and second active layers ACT1, ACT2 may include amorphous silicon, polycrystalline silicon, or the like. Alternatively, in embodiments, the first and second active layers ACT1, ACT2 may include an oxide semiconductor. In an embodiment example, the first and second active layers ACT1, ACT2 may include indium-gallium-zinc oxide (IGZO), indium-gallium oxide (IGO), indium-zinc oxide (IZO), or the like.

The gate insulating layer GI may be disposed on the buffer layer BUF. The gate insulating layer GI may be disposed to cover the first and second active layers ACT1, ACT2. The gate insulating layer GI may include an insulating material. Examples of the material that may be used as the gate insulating layer GI may include silicon oxide (“SiOx”), silicon nitride (“SiNx”), silicon oxynitride (“SiON”), and the like. These may be used alone or in combination with each other.

The first and second gate electrodes GE1, GE2 may be disposed on the gate insulating layer GI. The first and second gate electrodes GE1, GE2 may respectively overlap the first and second active layers ACT1, ACT2. In response to a gate signal (e.g., electrical signal) provided to the first and second gate electrodes GE1, GE2, a signal and/or a voltage as an electrical signal may flow through the first and second active layers ACT1, ACT2. In an embodiment, the first and second gate electrodes GE1, GE2 may include a metal, an alloy, a metal oxide, a transparent conductive material, or the like. In an embodiment, for example, the first and second gate electrodes GE1, GE2 may include silver (“Ag”), an alloy containing silver, molybdenum (“Mo”), an alloy containing molybdenum, aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide (ITO), indium zinc oxide (IZO), and the like.

The interlayer insulating layer ILD may be disposed on the gate insulating layer GI. The interlayer insulating layer ILD may be disposed to cover the first and second gate electrodes GE1, GE2. In an embodiment, the interlayer insulating layer ILD may include an insulating material. Examples of the material that may be used as the interlayer insulating layer ILD may include silicon oxide (“SiOx”), silicon nitride (“SiNx”), silicon oxynitride (“SiON”), and the like. These may be used alone or in combination with each other.

The first and second source electrodes SE1, SE2 and the first and second drain electrodes DE1, DE2 may be disposed on the interlayer insulating layer ILD. The first source electrode SE1 and the first drain electrode DE1 may contact the first active layer ACT1, such as to be electrically connected to the first active layer ACT1. The second source electrode SE2 and the second drain electrode DE2 may contact the second active layer ACT2, such as to be electrically connected to the first active layer ACT1. In an embodiment, each of the first and second source electrodes SE1, SE2 and the first and second drain electrodes DE1, DE2 may include a metal, an alloy, a metal oxide, a transparent conductive material, or the like. In an embodiment, for example, each of the first and second source electrodes SE1, SE2 and the first and second drain electrodes DE1, DE2 may include silver (“Ag”), an alloy containing silver, molybdenum (“Mo”), an alloy containing molybdenum, aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide (ITO), indium zinc oxide (IZO), and the like.

The via insulating layer VIA may be disposed on the interlayer insulating layer ILD. The via insulating layer VIA may be disposed to cover the first and second source electrodes SE1, SE2 and the first and second drain electrodes DE1, DE2. In an embodiment, the via insulating layer VIA may include an organic insulating material. In an embodiment, for example, the via insulating layer VIA may include a photoresist, a polyacrylic resin, a polyimide resin, an acrylic resin, or the like. The via insulating layer VIA may have a substantially flat top surface.

The substrate SUB, the buffer layer BUF, the gate insulating layer GI, the interlayer insulating layer ILD, the via insulating layer VIA, the first transistor TFT1 and the second transistor TFT2, which are the above-described components, may together constitute a transistor substrate or a driving circuit substrate.

The first and second anode electrodes ANO1, ANO2 may be disposed on the via insulating layer VIA. The first and second anode electrodes ANO1, ANO2 may contact the first and second drain electrodes DE1, DE2, respectively. In an embodiment, each of the first and second anode electrodes ANO1, ANO2 may include a metal, an alloy, a metal oxide, a transparent conductive material, or the like. In an embodiment, for example, each of the first and second drain electrodes DE1, DE2 may include silver (“Ag”), an alloy containing silver, molybdenum (“Mo”), an alloy containing molybdenum, aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide (ITO), indium zinc oxide (IZO), and the like.

The pixel defining layer PDL may be disposed on the via insulating layer VIA. An opening exposing the first and second anode electrodes ANO1, ANO2 may be formed (or provided) in the pixel defining layer PDL. In an embodiment, the pixel defining layer PDL may include an organic material. In an embodiment, for example, the pixel defining layer PDL may include a photoresist, a polyacrylic resin, a polyimide resin, an acrylic resin, or the like.

The first and second light emitting layers EMB, EMR may be disposed on the first and second anode electrodes ANO1, ANO2, respectively. The first and second light emitting layers EMB, EMR may include an organic material emitting light of a predetermined color. The first and second light emitting layers EMB, EMR may emit the light based on an electrical potential difference between the first and second anode electrodes ANO1, ANO2 and the first and second cathode electrodes CATH1, CATH2.

The first and second cathode electrodes CATH1, CATH2 may be disposed on the first and second light emitting layers EMB, EMR. The first and second cathode electrodes CATH1, CATH2 may include silver metal, an alloy, a metal oxide, a transparent conductive material, or the like. In an embodiment, for example, the first and second cathode electrodes CATH1, CATH2 may include silver (“Ag”), an alloy containing silver, molybdenum (“Mo”), an alloy containing molybdenum, aluminum (“Al”), alloys containing aluminum, aluminum nitride (“AN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), scandium (“Sc”), indium tin oxide (ITO), indium zinc oxide (IZO), and the like.

A thin film encapsulation layer may be disposed on the cathode electrode CATH. The thin film encapsulation layer may have a structure in which a first inorganic thin film encapsulation layer ILE1, an organic thin film encapsulation layer OLE, and a second inorganic thin film encapsulation layer ILE2 are in order in a direction away from the substrate SUB or a light emitting element layer including the first and second light emitting diodes ED1, ED2.

A touch sensing layer may be disposed on the thin film encapsulation layer. The touch sensing layer may serve to sense an external input from outside the display device DD, such as from an external touch, an objected in proximity to the display device DD, etc. To this end, the touch sensing layer may have a structure in which the first insulating layer TILL the first touch electrodes TE1, the second insulating layer TIL2, and the second touch electrodes TE2 are in order in a direction away from the thin film encapsulation layer. The first touch electrodes TE1 may be connected to the second touch electrodes TE2 at or through a contact hole provided in a layer between the two electrode layers. The first and second touch electrodes TE1, TE2 may overlap a solid portion of the pixel defining layer PDL and may not overlap the first and second light emitting layers EMB, EMR at the opening in the pixel defining layer PDL which is between solid portions thereof. Accordingly, the first and second touch electrodes TE1, TE2 may not block light emitted from below the input sensing layer, such as from the light emitting element layer.

A first refractive layer LR1 may be disposed on the second insulating layer TIL2. The first refractive layer LR1 may include a plurality of refractive patterns HR spaced apart from each other along the first refractive layer LR1. A size, shape, cross-sectional profile, etc. of the plurality of refractive patterns HR may be adjusted so that a path of light emitted from a lower portion of the display device DD is directed in the third direction DR3. The plurality of refractive patterns HR may overlap the first light emitting layer EMB and the second light emitting layer EMR, respectively. An area (e.g., a planar area) of each of the plurality of refractive patterns HR may be larger than an area (e.g., a planar area) of the first light emitting layer EMB and the second light emitting layer EMR. Each of the light emitting layers may have a planar shape defined by outer edges, and a refractive pattern HR corresponding to a respective light emitting layer may extend further than each of the outer edges of the respective light emitting layer, in a direction along the substrate SUB. In an embodiment, for example, a plurality of refractive patterns HR include a plurality of first refractive patterns respectively corresponding to the plurality of first light emitting layers EMB, a second refractive pattern and a third refractive pattern respectively corresponding to the second light emitting layer EMR and the third light emitting layer EMG, and each of the plurality of first refractive patterns, the second refractive pattern and the third refractive pattern respectively extending further than each of the outer edges of the plurality of first light emitting layers EMB, the second light emitting layer EMR and the third light emitting layer EMG.

In an embodiment, for example, an area of the first light emitting layer EMB may be different from an area of the second light emitting layer EMR. In this case, an area of the refractive pattern HR overlapping the first light emitting layer EMB may be larger than an area of the first light emitting layer EMB, and an area of the refractive pattern HR overlapping the second light emitting layer EMR may be larger than an area of the second light emitting layer EMR. In this case, areas of the refractive patterns HR may be different from each other.

The plurality of refractive patterns HR may have a tapered shape in cross-section, defined by an inclined side surface at each of opposing sides of a respective refractive pattern. Also, a first height H1 of each of the plurality of refractive patterns HR in the third direction DR3 may be about 3.2 micrometers to about 5 micrometers. When the refractive pattern HR has a height of 3.2 micrometers or less, the refractive pattern HR may not effectively adjust an angle of light emitted from the lower portion to be directed in the third direction DR3. In addition, since a second height H2 of the first refractive layer LR1 is greater than or equal to about 5 micrometers, the height of the refractive pattern HR may be less than or equal to about 5 micrometers.

The first refractive layer LR1 may be disposed to cover the plurality of refractive patterns HR, the plurality of second touch electrodes TE2, and the second insulating layer TIL2. The first refractive layer LR1 may planarize the plurality of refractive patterns HR. The first refractive layer LR1 may have a lower refractive index than that of the refractive pattern HR. Due to a difference in refractive index between the refractive pattern HR and the first refractive layer LR1, a path of light emitted from the lower portion of the display device DD may be adjusted to face the third direction DR3.

The plurality of first black matrices BM1 may be disposed on the first refractive layer LR1. The plurality of first black matrices BM1 may be disposed to respectively overlap the second touch electrodes TE2. The plurality of first black matrices BM1 may block light spreading in the second direction DR2. Accordingly, the viewing angle of the light emitted from the display device DD may be adjusted by blocking of the light emitting in the second direction DR2. Also, the plurality of first black matrices BM1 may reduce or effectively prevent mixing of light emitted from the first light emitting layer EMB and light emitted from the second light emitting layer EMR. Within a light blocking layer, the plurality of first black matrices BM1 may include a material capable of blocking light. In an embodiment, for example, the plurality of first black matrices BM1 may be formed of (or include) a material including an organic pigment of a specific color (e.g., black). Accordingly, the plurality of first black matrices BM1 may block some of the light emitted from the lower portion. The plurality of first black matrices BM1 may correspond to the aforementioned black matrices BM.

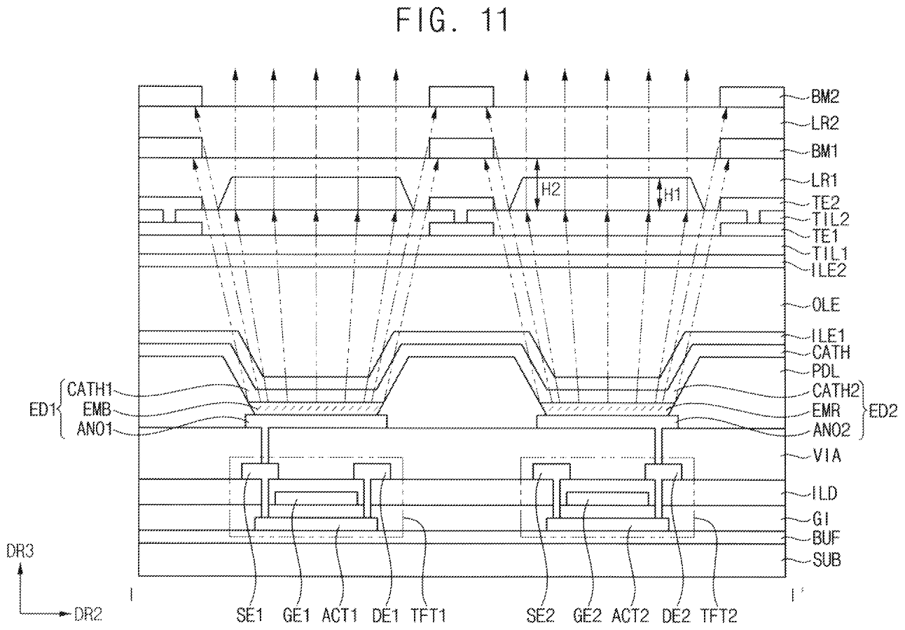

FIG. 11 is a cross-sectional view schematically illustrating an embodiment of a cross-section taken along line I-I′ of FIG. 2.

Referring to FIG. 11, FIG. 11 may be substantially the same as FIG. 10 except that a second refractive layer LR2 and second black matrices BM2 are further disposed. Accordingly, a description of the overlapping configuration will be omitted.

The second refractive layer LR2 may include substantially the same material as the first refractive layer LR1. The second black matrices BM2 may also include substantially the same material as the first black matrices BM1. The second black matrices BM2 may correspond to the aforementioned black matrices BM.

The second refractive layer LR2 may be disposed to cover the plurality of first black matrices BM1. The plurality of second black matrices BM2 may be disposed on the second refractive layer LR2. The plurality of second black matrices BM2 may be disposed to overlap the plurality of first black matrices BM1.

By disposing the second refractive layer LR2 and the plurality of second black matrices BM2, it is possible to further block light emitted from the lower portion of the display device DD from spreading in the second direction DR2.

Although not illustrated in the drawing, one or more of a refractive layer and one or more light blocking layer may be additionally stacked on the second refractive layer LR2 and the plurality of second black matrices BM2.

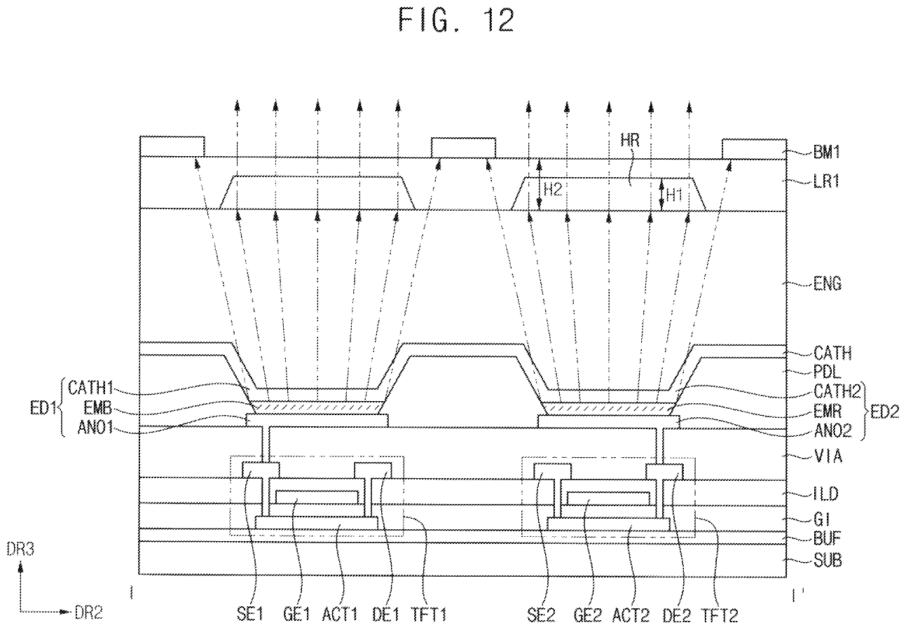

FIG. 12 is a cross-sectional view schematically illustrating other embodiment of a cross-section taken along line I-I′ of FIG. 2.

Referring to FIGS. 1, 2 and 12, the display device DD may include a substrate SUB, a buffer layer BUF, a gate insulating layer GI, an interlayer insulating layer ILD, a via insulating layer VIA, a first transistor TFT1, a second transistor TFT2, a first light emitting diode ED1, a second light emitting diode ED2, a pixel defining layer PDL, a glass layer ENG, a first refractive layer LR1 including the refractive patterns HR, and first black matrices BM1.

The first transistor TFT1 may include a first active layer ACT1, a first gate electrode GE1, a first source electrode SE1, and a first drain electrode DE1. The second transistor TFT2 may include a second active layer ACT2, a second gate electrode GE2, a second source electrode SE2, and a second drain electrode DE2.

The first light emitting diode ED1 may include a first anode electrode ANO1, a first light emitting layer EMB, and a first cathode electrode CATH1. The second light emitting diode ED2 may include a second anode electrode ANO2, a second light emitting layer EMR, and a second cathode electrode CATH2. The first cathode electrode CATH1 and the second cathode electrode CATH2 may be integrally formed. That is, each of the first cathode electrode CATH1 and the second cathode electrode CATH2 may be defined as a portion of the cathode electrode CATH.

The substrate SUB may include a flexible material or a rigid material. The buffer layer BUF may be disposed on the substrate SUB.

The first and second active layers ACT1, ACT2 may be disposed on the buffer layer BUF. The gate insulating layer GI may be disposed on the buffer layer BUF. The gate insulating layer GI may be disposed to cover the first and second active layers ACT1, ACT2. The first and second gate electrodes GE1, GE2 may be disposed on the gate insulating layer GI. The interlayer insulating layer ILD may be disposed on the gate insulating layer GI. The first and second source electrodes SE1, SE2 and the first and second drain electrodes DE1, DE2 may be disposed on the interlayer insulating layer ILD. The via insulating layer VIA may be disposed on the interlayer insulating layer ILD.

The first and second anode electrodes ANO1, ANO2 may be disposed on the via insulating layer VIA. The pixel defining layer PDL may be disposed on the via insulating layer VIA. The first and second light emitting layers EMB, EMR may be disposed on the first and second anode electrodes ANO1, ANO2, respectively. The first and second cathode electrodes CATH1, CATH2 may be disposed on the first and second light emitting layers EMB, EMR.

The glass layer ENG may be disposed on the cathode electrode CATH. When the glass layer ENG is disposed, the separate touch sensing layer may not be disposed. The glass layer ENG may function as an encapsulation layer. Accordingly, the first refractive layer LR1 may be disposed on the glass layer ENG. However, a separate touch film may be attached to the display device DD.

The first refractive layer LR1 may be disposed on the glass layer ENG. The first refractive layer LR1 may include a plurality of refractive patterns HR. The plurality of refractive patterns HR may be adjusted so that a path of light emitted from a lower portion of the display device DD is directed in the third direction DR3. The plurality of refractive patterns HR may overlap the first light emitting layer EMB and the second light emitting layer EMR, respectively. An area of each of the plurality of refractive patterns HR may be larger than an area of the first light emitting layer EMB and the second light emitting layer EMR. In an embodiment, for example, an area of the first light emitting layer EMB may be different from an area of the second light emitting layer EMR. In this case, an area of the refractive pattern HR overlapping the first light emitting layer EMB may be larger than an area of the first light emitting layer EMB, and an area of the refractive pattern HR overlapping the second light emitting layer EMR may be larger than an area of the second light emitting layer EMR. In this case, areas of the refractive patterns HR may be different from each other.

The plurality of refractive patterns HR may have a tapered shape. Also, a first height H1 of each of the plurality of refractive patterns HR in the third direction DR3 may be about 3.2 micrometers to about 5 micrometers. When the refractive pattern HR has a height of 3.2 micrometers or less, the refractive pattern HR may not effectively adjust a light emission direction so that light emitted from the lower portion is directed in the third direction DR3. In addition, since a second height H2 of the first refractive layer LR1 is typically greater than or equal to about 5 micrometers, the height of the refractive pattern HR may be less than or equal to about 5 micrometers.

The first refractive layer LR1 may be disposed to cover the plurality of refractive patterns HR and the glass layer ENG. The first refractive layer LR1 may have a lower refractive index than that of the refractive pattern HR. Due to a difference in refractive index between the refractive pattern HR and the first refractive layer LR1, a path of light emitted from the lower portion of the display device DD may be adjusted to face the third direction DR3.

The plurality of first black matrices BM1 may be disposed on the first refractive layer LR1. The plurality of first black matrices BM1 may be disposed to overlap the pixel defining layer PDL. The plurality of first black matrices BM1 may block light spreading in the second direction DR2. Accordingly, the viewing angle of the light emitted from the display device DD may be adjusted. Also, the plurality of first black matrices BM1 may prevent mixing of light emitted from the first light emitting layer EMB and light emitted from the second light emitting layer EMR. The plurality of first black matrices BM1 may include a material capable of blocking light. In an embodiment, for example, the plurality of first black matrices BM1 may be formed of a material including an organic pigment of a specific color (e.g., black). Accordingly, the plurality of first black matrices BM1 may block some of the light emitted from the lower portion.

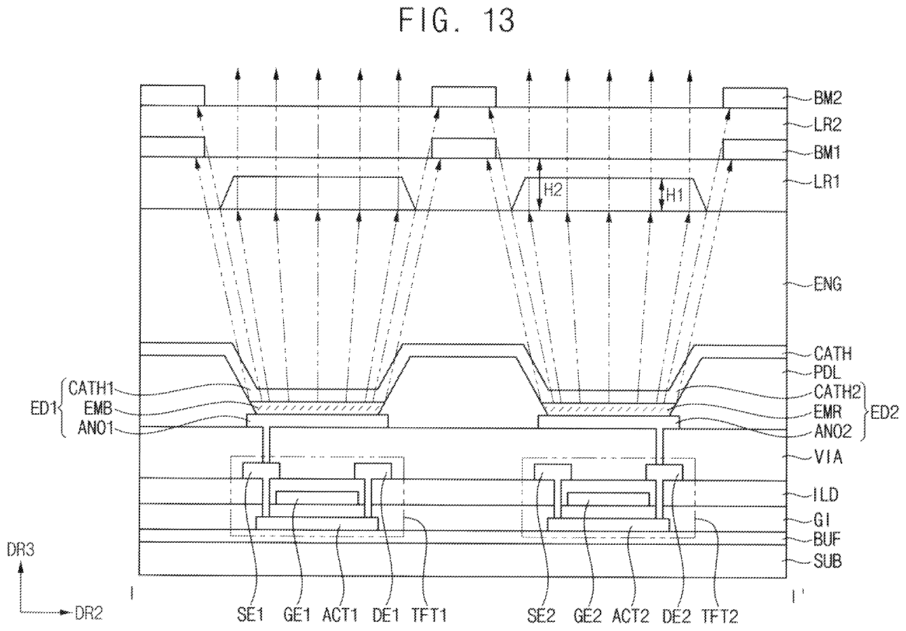

FIG. 13 is a cross-sectional view schematically illustrating an embodiment of a cross-section taken along line I-I′ of FIG. 2.

Referring to FIG. 13, FIG. 13 may be substantially the same as FIG. 12 except that a second refractive layer LR2 and a second black matrices BM2 are further disposed. Accordingly, a description of the overlapping configuration will be omitted.

The second refractive layer LR2 may include substantially the same material as the first refractive layer LR1. The second black matrices BM2 may also include substantially the same material as the first black matrices BM1. The second black matrices BM2 may correspond to the aforementioned black matrices BM.

The second refractive layer LR2 may be disposed to cover the plurality of first black matrices BM1. The plurality of second black matrices BM2 may be disposed on the second refractive layer LR2. The plurality of second black matrices BM2 may be disposed to overlap the plurality of first black matrices BM1.

By disposing the second refractive layer LR2 and the plurality of second black matrices BM2, it is possible to further block light emitted from the lower portion of the display device DD from spreading in the second direction DR2.

Although not illustrated in the drawing, one or more refractive layer and one or more light blocking layer may be additionally stacked on the second refractive layer LR2 and the plurality of second black matrices BM2.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a light emitting element layer comprising:
a first light emitting layer having a first length in a first direction and emitting a first light, and
a second light emitting layer spaced apart from the first light emitting layer along a second direction crossing the first direction, having a second length in the first direction and emitting a second light different from the first light;
a plurality of refractive patterns each having a first refractive index, the plurality of refractive patterns respectively corresponding to the first light emitting layer and the second light emitting layer;
a first refractive layer facing the first light emitting layer and the second light emitting layer, with the plurality of refractive patterns respectively therebetween, the first refractive layer having a second refractive index lower than the first refractive index of the plurality of refractive patterns; and
a light blocking layer comprising a plurality of first black matrices on the first refractive layer and arranged spaced apart from each other along the second direction with the plurality of refractive patterns therebetween.

2. The display device of claim 1, wherein the first length of the first light emitting layer is equal to the second length of the second light emitting layer.

3. The display device of claim 2, wherein within the light emitting element layer:
the first light emitting layer has a first width in the second direction which is smaller than the first length, and
the second light emitting layer has a second width in the second direction which is smaller than the second length.

4. The display device of claim 3, wherein the plurality of refractive patterns include:
a first refractive pattern corresponding to the first light emitting layer; and
a second refractive pattern corresponding to the second light emitting layer.

5. The display device of claim 4, wherein
each of the first light emitting layer and the second light emitting layer has a planar shape defined by outer edges,
the first refractive pattern extends further than each of the outer edges of the first light emitting layer, and
the second refractive pattern extends further than each of the outer edges of the second light emitting layer.

6. The display device of claim 1, wherein the first length of the first light emitting layer is larger than the second length of the second light emitting layer.

7. The display device of claim 6, wherein within the light emitting element layer:
the first light emitting layer has a first width in the second direction which is smaller than the first length, and
the second light emitting layer has a second width in the second direction which is smaller than the second width.

8. The display device of claim 7, wherein the first width of the first light emitting layer and the second width of the second light emitting layer are equal.

9. The display device of claim 7, wherein the plurality of refractive patterns include:
a first refractive pattern corresponding to the first light emitting layer; and
a second refractive pattern corresponding to the second light emitting layer.

10. The display device of claim 9, wherein
each of the first light emitting layer and the second light emitting layer has a planar shape defined by outer edges,
the first refractive pattern extends further than each of the outer edges of the first light emitting layer, and
the second refractive pattern extends further than each of the outer edges of the second light emitting layer.

11. The display device of claim 1, wherein the plurality of first black matrices include:
a first light blocking pattern and a second light blocking pattern spaced apart from each other along the second direction with the first light emitting layer therebetween, and
the second light blocking pattern closer to the second light emitting layer than the first light blocking pattern.

12. The display device of claim 11, wherein
the first light blocking pattern has the first length in the first direction, and
the second light blocking pattern has the first length in the first direction.

13. The display device of claim 11, wherein
the first light blocking pattern has the first length in the first direction, and
the second light blocking pattern has the second length in the first direction.

14. The display device of claim 1, wherein
the plurality of refractive patterns, the first refractive layer, and the light blocking layer are in order in a third direction crossing each of the first direction and the second direction, and
each of the plurality of refractive patterns has a height along the third direction which is about 3.2 micrometers to about 5 micrometers.

15. The display device of claim 1, further comprising:
a second refractive layer facing the first refractive layer with the plurality of first black matrices therebetween; and
a plurality of second black matrices respectively facing the plurality of first black matrices with the second refractive layer therebetween.

16. The display device of claim 1, further comprising an encapsulation layer between the light emitting element layer and the first refractive layer.

17. The display device of claim 16, further comprising a touch sensing layer between the encapsulation layer and the first refractive layer.

18. A display device, comprising:
a light emitting element layer comprising:
a plurality of first light emitting layers each having a first length in a first direction and each emitting a first light,
the plurality of first light emitting layers adjacent to each other in a second direction crossing the first direction to define a light emitting layer group, and
a second light emitting layer and a third light emitting layer each adjacent in the second direction to the light emitting layer group, each having a second length in the first direction and each emitting a second light different from the first light;
a plurality of refractive patterns each having a first refractive index, the plurality of refractive patterns respectively corresponding to the first light emitting layer, the second light emitting layer and the third light emitting layer;
a first refractive layer facing each of the first light emitting layer, the second light emitting layer and the third light emitting layer, with the plurality of refractive patterns respectively therebetween, the first refractive layer having a second refractive index lower than the first refractive index of the plurality of refractive patterns; and
a light blocking layer comprising a plurality of first black matrices on the first refractive layer and spaced apart from each other along the second direction with the plurality of refractive patterns therebetween.

19. The display device of claim 18, wherein
the first length of the plurality of first light emitting layers is larger than the second length of the second light emitting layer and the third light emitting layer, and
along the second direction, each of the plurality of first light emitting layers has a first width, the second light emitting layer has a second width and the third light emitting layer has a third width.

20. The display device of claim 19, wherein
the first widths of the plurality of first light emitting layers are different from each other within the light emitting layer group, and
the second width of the second light emitting layer is different from the third width of the third light emitting layer.

21. The display device of claim 19, wherein the first widths of the plurality of first light emitting layers are the same as each other within the light emitting layer group.

22. The display device of claim 18, wherein
each of the plurality of first light emitting layers, the second light emitting layer and the third light emitting layer has a planar shape defined by outer edges; and
the plurality of refractive patterns include:
a plurality of first refractive patterns respectively corresponding to the plurality of first light emitting layers;
a second refractive pattern and a third refractive pattern respectively corresponding to the second light emitting layer and the third light emitting layer; and
each of the plurality of first refractive patterns, the second refractive pattern and the third refractive pattern respectively extending further than each of the outer edges of the plurality of first light emitting layers, the second light emitting layer and the third light emitting layer.

23. The display device of claim 18, wherein
each of the plurality of first light emitting layers, the second light emitting layer and the third light emitting layer has a planar area,
each of the plurality of refractive patterns has a planar area, and
the planar areas of the plurality of refractive patterns are respectively larger than the planar areas of the plurality of first light emitting layers, the second light emitting layer and the third light emitting layer.

24. The display device of claim 18, wherein
the plurality of refractive patterns, the first refractive layer, and the light blocking layer are in order in a third direction crossing each of the first direction and the second direction, and
each of the plurality of refractive patterns has a height along the third direction which is about 3.2 micrometers to about 5 micrometers.

25. The display device of claim 18, further comprising:
a second refractive layer facing the first refractive layer with the plurality of first black matrices therebetween; and
a plurality of second black matrices respectively facing the plurality of first black matrices with the second refractive layer therebetween.

26. The display device of claim 18, further comprising:
an encapsulation layer between the light emitting element layer and the first refractive layer; and
a touch sensing layer between the encapsulation layer and the first refractive layer.

27. The display device of claim 18, further comprising a glass layer between the light emitting element layer and the first refractive layer.
